(19) United States
(12) Patent Application Publication
(10) Pub. No.: US 2005/0246599 A1
(43) Pub. Date: Nov. 3, 2005

(54) System and method for testing input and output characterization on an integrated circuit device

(75) Inventors: Neil John Simpson, Rockwall, TX (US); Rakesh Kumar, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/836,931

(22) Filed: Apr. 30, 2004

(51) Int. Cl. G01R 31/28

(52) U.S. Cl. 714/724

(57) ABSTRACT

A system for testing input characteristics of an integrated circuit device includes an integrated circuit device. The integrated circuit device includes, an input pad, an output pad, an input register, and a data register. The input register receives an input value from the input pad and communicates the input value to a portion of the integrated circuit for processing when the integrated circuit is not in test mode. The data register receives a test value from the input register and communicates the test value to the output pad when the integrated circuit is in test mode.

### TECHNICAL FIELD OF THE INVENTION

This invention relates generally to the field of integrated circuits and, more specifically, to a system and method for testing input and output characterization on an integrated circuit device.

### BACKGROUND OF THE INVENTION

Semiconductor manufacturers typically test the input/output characteristics of their integrated circuit devices. Input characteristics of an integrated circuit device may include setup time and hold time. Setup time and hold time describe the timing requirements of the D input of a flip-flop with respect to a clock input. Specifically, setup time and hold time define a window of time within which the D input must be valid and stable to ensure valid data on the Q output of the flip-flop. Setup time is the time that the D input must be valid before the flip-flop samples, and hold time is the time that the D input must be maintained valid after the flip-flop samples. Output characteristics of an integrated circuit may include propagation delay, which is the time it takes the D input to propagate to the Q output and from the Q output to the output pad.

Currently, for each integrated circuit, engineers must write input/output characterization test patterns that exercise the functionality of each interface, as well as the internal bridges and functions of each interface within the integrated circuit. As a result, input/output characterization is an expensive process that requires substantial engineering time to design, develop, debug, and implement suitable test patterns.

### SUMMARY OF THE INVENTION

In accordance with the present invention, a system and method for testing input and output characterization on an integrated circuit device is provided that substantially eliminates or reduces disadvantages or problems associated with previously developed systems and methods.

In one embodiment, a system for testing input characteristics of an integrated circuit device includes an integrated circuit device. The integrated circuit device includes, an input pad, an output pad, an input register, and a data register. The input register receives an input value from the input pad and communicates the input value to a portion of the integrated circuit for processing when the integrated circuit is not in test mode. The data register receives a test value from the input register and communicates the test value to the output pad when the integrated circuit is in test mode.

In another embodiment, a system for testing input characteristics of an integrated circuit device includes an integrated circuit device. The integrated circuit device includes an input pad, an output pad, and a output register. The input pad receives an input value for use in testing propagation delay. The output register receives the input value from the input pad when the integrated circuit device is in test mode and communicates the input value to the output pad in response to a clock event.

The present invention provides a number of important technical advantages. Unlike previous techniques, the present invention incorporates test structures into an integrated circuit to allow a semiconductor manufacturer to substantially remove the functional requirements of an integrated circuit from the design, development, and implementation of test patterns for input/output characterization. As a result, the testing of input/output characteristics requires less time, resources, and expense. For these and other readily apparent reasons, the present invention represents a significant advance over prior art systems and methods.

### BRIEF DESCRIPTION OF THE DRAWINGS

FIG. 1 illustrates a system for testing the input characteristics of an integrated circuit device;

FIG. 2 illustrates a system for testing the output characteristics of an integrated circuit device;

FIG. 3 illustrates configuration registers that may be used to select an input or output path in an integrated circuit device for testing purposes;

FIG. 4 is a flowchart of a method of testing input characteristics in an integrated circuit device; and

FIG. 5 is a flowchart of a method of testing output characteristics in an integrated circuit device.

### DETAILED DESCRIPTION OF THE DRAWINGS

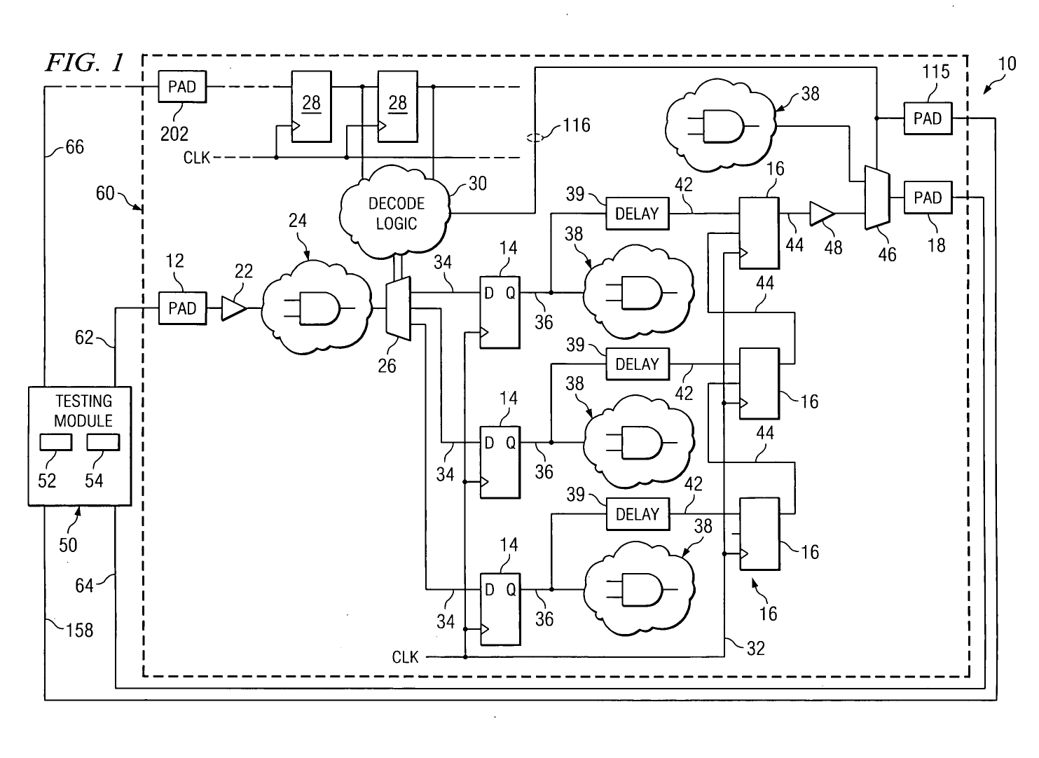

FIG. 1 illustrates a system 10 for testing the input characteristics of an integrated circuit device. System 10 includes testing module 50 and integrated circuit device 60.

Testing module 50 performs a test pattern that tests the input characteristics of an input path of integrated circuit device 60. In the illustrated embodiment, testing module 50 includes a processing module 52 and memory 54. Processing module 52 may include hardware, software or a combination of hardware and software suitable to execute programmed instruction for testing integrated circuit device 60. Memory 54 may include random access memory (RAM), read only memory (ROM), hard drives, or any other suitable storage device for storing programmed instructions or data used by processing module 52.

Integrated circuit device 60 includes an input pad 12, input registers 14, data registers 16, and an output pad 18. Links 62 and 64 couple testing module 50 to input pad 12 and output pad 18, respectively. Link 62 communicates information from testing module 50 to integrated circuit device 60, and link 64 communicates information from integrated circuit device 60 to testing module 50. Link 66 communicates configuration information to configuration registers 28. Links 62, 64, and 66 may use wireless, wireline, or any other technology suitable for communicating information between testing module 50 and integrated circuit device 60.

Input pad 12 receive an input value and communicates the input value to one or more input registers 14. The input value may be a low voltage (typically represented as a “0”) or a high voltage (typically represented as a “1”). When integrated circuit device 60 is in test mode, input pad 12 receives the input value form testing module 50 using link 62.

The communication path from input pad 12 to input registers 14 may include one or more intermediate structures. For example, in the particular embodiment illustrated in FIG. 1, the communication path includes an input buffer 22. In an alternative embodiment, input pad 12 may be a common interface input/output pad which both sends and receives information when integrated circuit device 60 is not in test mode, and in such an embodiment, the communication path may include an input/output or IO buffer. Although not illustrated in FIG. 1, an alternative embodiment may include an IEEE Standard 1149.1 (JTAG) boundary scan register in the communication path between input pad 12 and input register 14.

As shown in the particular embodiment illustrated in FIG. 1, the communication path may include logic 24 or a demultiplexer 26. In the illustrated embodiment, input pad 12 communicates with several input registers 14. As explained in further detail below, configuration registers 28 and decode logic 30 provide control signals to demultiplexer 26 to select one of D inputs 34 associated with one of input registers 14 for testing purposes. In an alternative embodiment, input pad 12 may communicate with one input register 14, and the communication path between input pad 12 and input register 14 may not include logic 24 or demultiplexer 26.

Input register 14 receives an input value at D input 34, stores the received input value, and communicates the input values to Q output 36. In the illustrated embodiment, input register 14 is a flip-flop which operates according a clock signal 32. At a clocking event, input register 14 receives the value at D input 34, stores that value, and communicates that value to Q output 36. In a particular embodiment, the clocking event is the rising edge of clock signal 32 (i.e., when clock signal 32 rises from a low voltage to a high voltage). In an alternative embodiment, the clocking event is the falling edge of clock signal 32 (i.e., when clock signal 32 falls from a high voltage to a low voltage). When input register 14 detects a clocking event, input register 14 samples the input value at D input 34, stores the input value, and communicates the input value to Q output 36. When integrated circuit device 60 is not in test mode, the value at Q output 36 is communicated to internal logic 38 which uses the value to implement the programmed functionality of integrated circuit device 60. When integrated circuit device 60 is in test mode, the value at Q output 36 is communicated to data register 16, so that it can be communicated to testing module 50 to test the input characteristics of integrated circuit device 60.

As described above, the input characteristics of integrated circuit device 60 include the timing requirements of D input 34 of input register 14 with respect to clock signal 32. Specifically, setup time and hold time are two input characteristics which define a window of time within which D input 34 must be valid and stable to ensure valid data on Q output 36 of input register 14. Setup time is the time that D input 34 must be valid before input register 14 samples, and hold time is the time that D input 34 must be valid after input register 14 samples. In other words, if the input value is a “1” (or high voltage), the input pad 12 must maintain a “1” (or high voltage) at D input 34 for at least the setup time period before the clocking event and the hold time period after the clocking event.

Data registers 16 receive the values stored at input registers 14 and communicates the values to output pad 18 when integrated circuit device 60 is in test mode. In the particular embodiment illustrated in FIG. 1, data registers 16 are implemented as a serial scan chain. Like input registers 14, data registers 16 operate according to clock signal 32. At a clocking event, data register 16 receives the value at its input 42, stores that value, and communicates that value to its Q output 44. In a particular embodiment, the clocking event is the rising edge of clock signal 32 (i.e., when clock signal 32 rises from a low voltage to a high voltage). In an alternative embodiment, the clocking event is the falling edge of clock signal 32 (i.e., when clock signal 32 falls from a high voltage to a low voltage). Once the values are stored in data registers 16, data registers 16 may shift the stored values to output pad 18 in a serial manner.

In the particular embodiment illustrated in FIG. 1, integrated circuit device 60 includes delays 39 between input registers 14 and data registers 16. These delays 39 may be necessary to detect potential metastability problems in input registers 14. In a particular embodiment, the time of the delay equals the time period of the clock minus the sum of the propagation delay of inputed registers 14 and the setup time of data registers 16. In alternative embodiments, semiconductor device 60 may not include delays 39 between input registers 14 and data registers 16 because delays 39 may not be necessary to detect potential metastability.

Output pad 18 receives the values stored in data registers 16. In the particular embodiment illustrated in FIG. 1, output pad 18 is also used when integrated circuit device 60 is not in test mode, and for this reason, the communication path between data registers 16 and output pad 18 includes a multiplexer 46. Multiplexer 46 communicates the value from data register 16 to output pad 18 when integrated circuit device 60 is in test mode and communicates the value from internal logic 38 to output pad 18 when integrated circuit device 60 is not in test mode. In the particular embodiment illustrated in FIG. 1, the communication path also includes an output buffer 48. In an alternative embodiment, output pad 18 may be a common interface input/output pad which both sends and receives information when integrated circuit device 60 is not in test mode, and in such an embodiment, the communication path may include an input/output or IO buffer.

Testing module 50 performs input characterization by testing the setup and hold times of integrated circuit device 60. To identify the setup time of a particular input path, testing module 50 performs various test patterns to test the input path with different test setup times between the setting of the input value at input pad 12 and the clocking event at input register 14, and testing module 50 determines the minimum setup time at which input register 14 receives the value at input pad 12. In the particular embodiment described below, the test input value is a “1” (or high voltage), and testing module 50 begins with a test setup time greater than the expected setup time (so that input register 14 receives the test input value) and performs a linear search by incrementally decreasing the test setup times until input register 14 fails to receive the test input value. In each test pattern, data register 16 captures the value stored by input register 14 and communicates the value to output pad 18. The minimum test setup time at which the output value is a “1” (or high voltage) is the setup time.

In each test pattern, input register 14 and data register 16 are set to “0” (or a low voltage). In a particular embodiment, a reset control signal is used to set input register 14 and data register 16 to “0” (or a low voltage). In an alternative embodiment, a “0” value is loaded into input register 14 and data register 16 using input pad 12. Next, testing module 50 sets input pad 12 to a test input value of “1” (or high voltage) at a test setup time before the clocking event. At the clocking event, input register 14 receives the value at D input 34 and communicates the value to Q output 36. At the next clocking event, data register 16 receives the value at its input 42 and communicates the value to its output 44. Data registers 16 communicates the value to output pad 18. In a particular embodiment, data registers 16 serially shift the value to output pad 18. Testing module 50 receives the output value at output pad 18 compares the output value with the test input value to determine whether input register 14 received the input value at input pad 12 when the input value was set at input pad 12 at the test setup time before the clocking event. In this particular embodiment, testing module 50 determines whether the value received from output pad 18 is a “1” (or high voltage). At the first run of this test pattern, the test setup time should be greater than the expected setup time, and as a result, input register 14 will receive the test input value (in this example, the “1” or high voltage) at the clocking event, which will be reflected by the output value at output pad 18 at the end of the test pattern. The test pattern is modified by decreasing the test setup time, and testing module 50 performing the test pattern again. Eventually input register 14 will not receive the test input value (in this example, the “1” or high voltage) because the delay between setting the input value at input pad 12 and the clocking event is too short. When this happens, testing module 50 will detect that the output value received from output pad 18 does not match the test input value. As a result, testing module 50 will identify the prior test setup time (the last one with which input register 14 received the test input value) as the setup time of the tested input path. In this manner, testing module 50 can execute a linear search to the find the shortest setup time at which the input path is still functional (i.e., input register 14 continues to receives the test input value). Testing module 50 may perform this search several times to ensure the validity of the results.

In an alternative embodiment, testing module 50 can perform a linear search by starting with a test setup time that is less that the expected setup time (so that input register 14 will not receive the test input value at the clocking event) and modifying the test patterns by increasing the test setup time until input register 14 receives the test input value. In still other embodiments, system 10 may search for the setup time for the input path using a searching technique other than a linear search.

In a similar manner, testing module 50 can test the hold time of integrated circuit device 60. To determine the hold time for a particular input path, testing module 50 performs various test patterns to test different holding periods (the time period after the clocking event that the input value is maintained at input pad 12), and testing module 50 determines the minimum holding period at which input register 14 receives and stores a valid input value from input pad 12. In the particular embodiment described below, the test input value is a “1” (or high voltage), and testing module 50 begins the test using a test pattern with a holding period greater than the expected hold time (so that input register 14 receives the test input value) and performs a linear search by incrementally decreasing the holding period until input register 14 fails to receive the test input value. In each test pattern, data register 16 captures the value stored by input register 14 and communicates the value to output pad 18. The minimum holding period at which the output value is a “1” (or high voltage) is the hold time.

In each test pattern, input register 14 and data register 16 are set to “0” (or a low voltage). In a particular embodiment, a reset control signal is used to set input register 14 and data register 16 to “0” (or a low voltage). In an alternative embodiment, a “0” value is loaded into input register 14 and data register 16 using input pad 12. Next, the input value at input pad 12 is set to a “1” (or high voltage) at least the setup time before the clocking event and that input value is maintained for a test holding period after the clocking event that is greater than the expected hold time. At the clocking event, input register 14 receives the input value at D input 34 and communicates the value to Q output 36. At the next clocking event, data register 16 receives the value at it input 42 and communicates that value to output 44. Data register 16 communicates the received value to output pad 18. In a particular embodiment, data registers 16 serially shift the value to output pad 18. Testing module 50 receives the output value from output pad 18 and compares the output value to the test input value to determine whether input register 14 received the test input value (the “1” or high voltage) at input pad 12 with the test input value being maintained at input pad 12 for the test holding period after the clocking event. At the first run of this test pattern, the test holding period should be greater than the expected hold time, and as a result, input register 14 will receive the test input value (in this example, the “1” or high voltage) at the clocking event, which will be reflected by the output value at output pad 18 at the end of the test pattern. Testing module 50 modifies the test pattern by decreasing the test holding period, and the test pattern is performed again. Eventually input register 14 will not receive the test input value (in this example, the “1” or high voltage) because the test holding period after the clocking event is too short. When this happens, testing module 50 will detect that the output value received from output pad 18 does not match the test input value. As a result, testing module 50 will identify the prior test holding period (the last one with which input register 14 received the test input value) as the holding time of the tested input path. In this manner, testing module 50 can execute a linear search to the find the shortest holding period at which the input path is still functional (i.e., input register 14 receives the input value at input pad 12). Testing module 50 may perform this search several times to ensure the validity of the results.

In an alternative embodiment, testing module 50 can perform a linear search by starting with a test holding period that is less that the expected hold time (so that input register 14 will not receive the test input value at the clocking event) and modifying the test patterns to increase the test holding period until input register 14 receives the test input value. In still other embodiments, system 10 may search for the hold time using a searching technique other than a linear search.

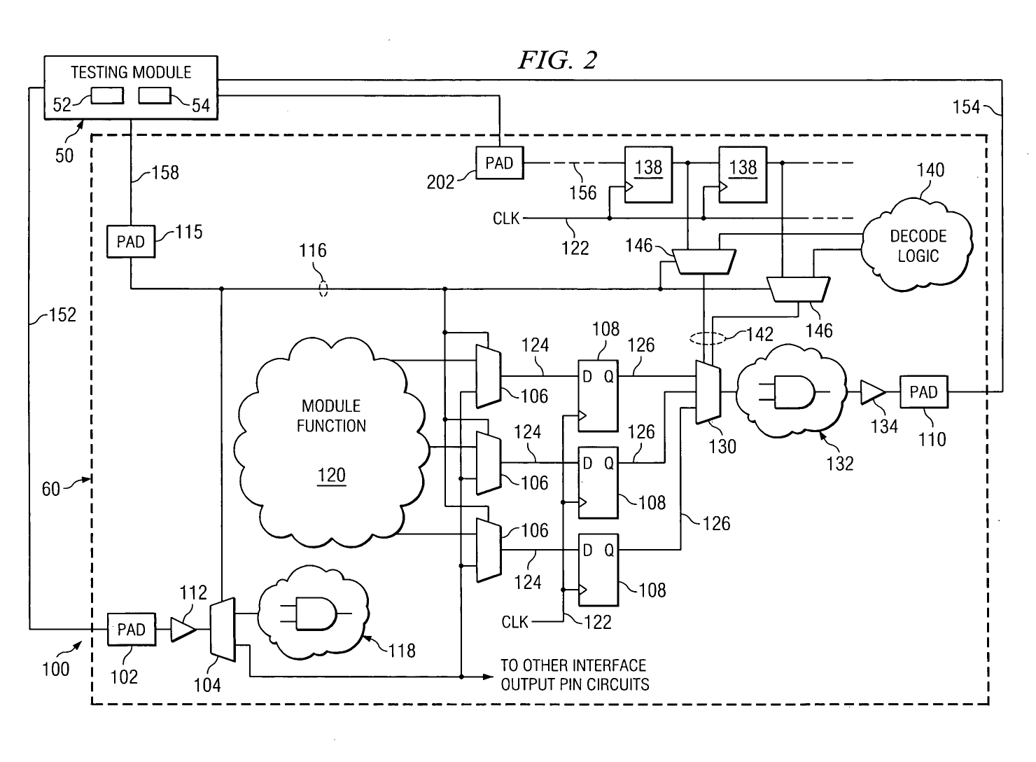

FIG. 2 illustrates a system 100 for testing the output characteristics of integrated circuit device 60. System 100 includes testing module 50 and integrated circuit device 60.

Testing module 50 performs a test pattern that tests the output characteristics of an output path of integrated circuit device 60. In the illustrated embodiment, testing module 50 includes a processing module 52 and memory 54. Processing module 52 may include hardware, software or a combination of hardware and software suitable to execute programmed instruction for testing integrated circuit device 60. Memory 54 may include random access memory (RAM), read only memory (ROM), hard drives, or any other suitable storage device for storing programmed instructions or data used by processing module 52.

Integrated circuit device 60 includes input pad 102, demultiplexer 104, and multiplexers 106, output registers 108, and output pad 110, all of which are implemented in the integrated circuit device.

Links 152, 154, 156, and 158 couple testing module 50 and integrated circuit device 60 to one another. Link 152 communicates input test values from testing module 50 to input pad 102 of integrated circuit device 60. Link 154 communicates output test values from output pad 110 of integrated circuit device 60 to testing module 50. Link 156 communicates configuration information from testing module 50 to configuration registers 138. In the particular embodiment illustrated in FIG. 2, testing module 50 generates test mode signal 116 and communicates test mode signal 116 to demultiplexer 104 and multiplexers 106 and 146 using link 158. Links 152, 154, 156, and 158 use wireless, wireline, or any other technology suitable for communicating information between testing module 50 and integrated circuit device 60. Links 152, 154, 156 and 158 may include intermediate components.

Input pad 102 receives a test input value and communicates the test input value to output registers 108. The input value may be a low voltage (typically represented as a “0”) or a high voltage (typically represented as a “1”).

The communication path from input pad 102 to output registers 108 may include one or more intermediate structures. For example, in the particular embodiment illustrated in FIG. 2, the communication path includes an input buffer 112. In an alternative embodiment, input pad 102 may be a common interface input/output pad which both sends and receives information when integrated circuit device 60 is not in test mode, and in such an embodiment, the communication path may include an input/output or IO buffer. Although not illustrated in FIG. 1, an alternative embodiment may include an IEEE Standard 1149.1 (JTAG) boundary scan register in the communication path between input pad 102 and output register 108.

Demultiplexer 104 and multiplexer 106 establish a communication path between input pad 102 and output registers 108 when integrated circuit device 60 is in test mode. Test mode signal 116 indicates whether integrated circuit device 60 is in test mode. In a particular embodiment, test mode signal 116 is “1” (or a high voltage) when integrated circuit device 60 is in test mode, and test mode signal 116 is “0” (or a low voltage) when integrated circuit device 60 is not in test mode. In an alternative embodiment, integrated circuit device 60 may include several different modes of operations, and as a result, integrated circuit device 60 may uses more than one signal 116 to indicate whether integrated circuit device 60 is in test mode.

When integrated circuit device 60 is in test mode, demultiplexer 104 (together with multiplexers 106) establishes a communication path between input pad 102 and output registers 108, so that testing module 50 can use input pad 102 to communicate test values to output registers 108 for use in testing propagation delay. When integrated circuit device 60 is not in test mode, demultiplexer 104 establishes a communication path between input pad 102 and some other portion of integrated circuit device 60 (represented as internal logic 118 in the illustrated embodiment), so that input pad 102 may used as an input and/or output when integrated circuit device 60 is not in test mode. In an alternative embodiment, input pad 102 may not be used for other purposes when integrated circuit device 60 is not in test mode, and thus, integrated circuit device 60 may not include demultiplexer 104.

When integrated circuit device 60 is in test mode, multiplexers 106 establish a communication path between input pad 102 and output registers 108. When integrated circuit device 60 is not in test mode, multiplexers 106 establish a communication path between some other portion of the integrated circuit (represented as module function 120 in the illustrated embodiment) and output register 108, so that output registers 108 and output pad 110 can be used to communicate information from integrated circuit device 60. As shown in FIG. 2, when integrated circuit device 60 is in test mode, system 100 allows testing module 50 to communicate test values to output registers 108 while bypassing a portion of integrated circuit device 60 (represented as internal logic 118 in the illustrated embodiment).

Output register 108 receives an output values at a clocking event and communicates the output value to output pad 110. In the illustrated embodiment, output register 108 is a flip-flop which operates according a clock signal 122. In a particular embodiment, the clocking event is the rising edge of clock signal 122 (i.e., when clock signal 122 rises from a low voltage to a high voltage). In an alternative embodiment, the clocking event is the falling edge of clock signal 122 (i.e., when clock signal 122 falls from a high voltage to a low voltage). When output register 108 detects the clock event, output register 108 samples the value at D input 124, stores the value, and communicates the value to Q output 126. When integrated circuit device 60 is in test mode, output register 108 receives a test value at D input 124 from input pad 102. When integrated circuit device 60 is not in test mode, output register 108 receives an output value at D input 124 from module function 120.

As described above, an output characteristic of integrated circuit device 60 is propagation delay, which is the time it takes the value at D input signal 124 to propagate to Q output signal 126 and to output pad 110. As shown in the particular embodiment illustrated in FIG. 2, the communication path from output registers 108 to output pad 110 may include multiplexer 130, logic 132, buffer 134, or any other suitable intermediate structures. In the particular embodiment illustrated in FIG. 2, the communication path to output pad 110 includes output buffer 134. In an alternative embodiment, output pad 110 may be a common interface input/output pad which both sends and receives information when integrated circuit device 60 is not in test mode, and in such an embodiment, the communication path may include an input/output or IO buffer. Although not illustrated in FIG. 2, the communication path between output registers 108 and output pad 110 may include an IEEE Standard 1149.1 (JTAG) boundary scan register or other additional intermediate structures. These intermediate structures may add time to the propagation delay from output registers 108 to output pad 110.

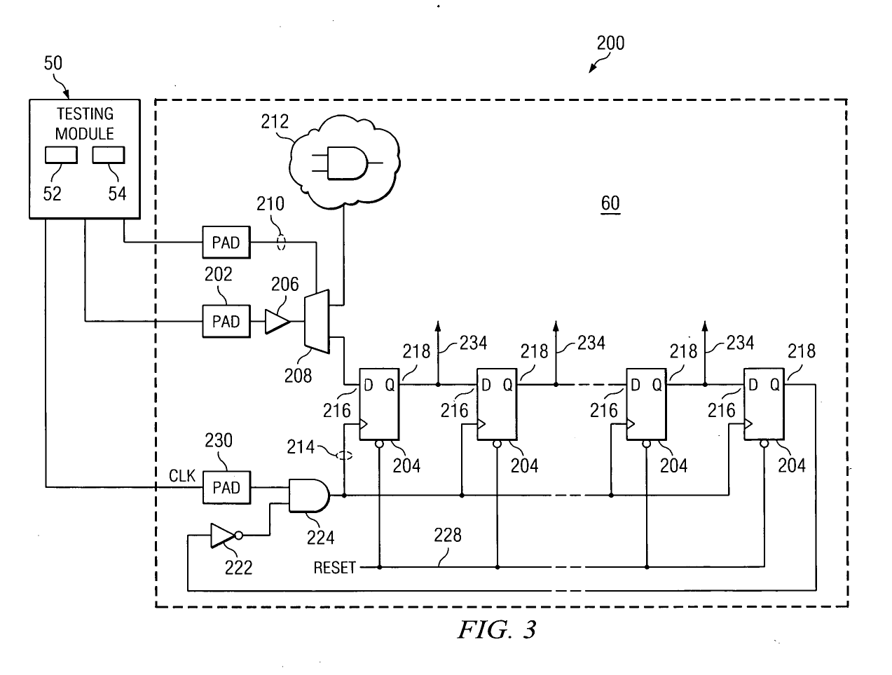

Integrated circuit device 60 may have more than one output communication path to output pad 110 that requires testing for propagation delay. In the illustrated embodiment, three output registers 108 can communicate output values to output pad 110, which means that integrated circuit device 60 includes three different communication paths which may be tested for propagation delay. Multiplexer 130 completes one of the three possible communication paths between output registers 108 and output pad 110 according to output path control signals 142. When integrated circuit device 60 is in test mode, multiplexers 146 couple configuration registers 138 to multiplexer 130, and, configuration registers 138 may be programmed to generate output path control signals 142 and select one of the output communication paths for testing. When integrated circuit device 60 is not in test mode, multiplexers 146 couple decode logic 140 to multiplexer 130, and decode logic 140 generates output path control signals 142 to select one of the output communication paths according to the particular operations and functionality of integrated circuit device 60. FIG. 3, which is described below, illustrates a manner of programming configuration registers 138 to select output or input communication paths for testing. In an alternative embodiment, integrated circuit device 60 may include additional logic between configuration registers 138 and multiplexer 130 to reduce the number of configuration registers 138 necessary to select communication paths for testing.

In an alternative embodiment, only one output register 108 may communicate with output pad 110, eliminating the need for multiplexer 130, configuration registers 138, decode logic 140, and multiplexers 146.

When integrated circuit device 60 is in test mode, testing module 50 may test the propagation delay of a selected output communication path without having to exercise the normal functionality of integrated circuit device 60, such as module function 120. In the particular embodiment illustrated in FIG. 2, testing module 50 generates test mode signal 116 and communicates test mode signal 116 to demultiplexer 104 and multiplexers 106 using link 158. As explained above, test mode signal 116 causes demultiplexer 104 and multiplexers 106 to establish a communication path from input pad 102 to output registers 108. With this communication path, testing module 50 can use input pad 102 to communicate a test value to output registers 108, which receive the test value at a clocking event of clock signal 122. Testing module 50 can determine the propagation delay of an output communication path by measuring the delay from after the clocking event until the time when the test value appears at output pad 110.

For example, in this example, the test value is “1” (or a high voltage). Testing module 50 sets output registers 108 to “0” (or a low voltage). In a particular embodiment, testing module 50 uses a reset control signal to set output registers 108 to “0” (or a low voltage). In an alternative embodiment testing module 50 uses input pad 102 to communicate a “0” value to D inputs 124 of output registers 108, which receive the “0” at a clocking event of clock signal 122. Testing module 50 applies the test value, a “1” (or a high voltage), to input pad 102, and at the next clocking event of clock signal 122, output registers 108 receive the test value, and one of output registers 108 (the one coupled to output pad 110 by multiplexer 130) communicates the test value to output pad 110. By measuring the time period between the clocking event and the appearance of the test value at output pad 110, testing module 50 can determine the propagation delay of the particular output communication.

By programming configuration registers 138 to select different output communication paths, testing module 50 can determine the propagation delays of these different communication paths. In a particular embodiment, testing module 50 can test several communication paths associated with different output pads 110 at the same time.

FIG. 3 illustrates a system 200 for selecting an input or output path in integrated circuit device 60 for testing. System 200 includes testing module 50 and integrated circuit device 60. Integrated circuit device 60 includes configuration data input pad 202 and configuration registers 204. As described above, input pad 12 in FIG. 1 may communicate information to more than one input register 14, and configuration registers 204 can be programmed to select one of the input communication paths to one of input registers 14 for testing purposes. Similarly, output pad 110 in FIG. 2 may receive information from more than one output register 108, and configuration registers 204 can be programmed to select one of the output communication paths from one of the output registers 108 to output pad 110 for testing purposes.

When integrated circuit device 60 is in test mode, configuration data input pad 202 receives configuration data from testing module 50 and communicates the configuration data to configuration registers 204. The communication path from configuration data input pad 202 to configuration registers 204 may include one or more intermediate structures. For example, in the particular embodiment illustrated in FIG. 3, the communication path includes an input buffer 206. In an alternative embodiment, configuration data input pad 202 may be a common interface input/output pad which both sends and receives information when integrated circuit device 60 is not in test mode, and in such an embodiment, the communication path may include an input/output or IO buffer. Although not illustrated in FIG. 3, an alternative embodiment may include an IEEE Standard 1149.1 (JTAG) boundary scan register in the communication path between configuration data input pad 202 and configuration registers 204.

Demultiplexer 208 establishes a communication path between configuration data input pad 202 and configuration registers 204 when integrated circuit device 60 is in test mode. Test mode signal 210 indicates whether integrated circuit device 60 is in test mode. In a particular embodiment, test mode signal 210 is “1” (or a high voltage) when integrated circuit device 60 is in test mode, and test mode signal 210 is “0” (or a low voltage) when integrated circuit device 60 is not in test mode. In an alternative embodiment, integrated circuit device 60 may include several different modes of operations, and as a result, integrated circuit device 60 may use more than one signal 210 to indicate whether integrated circuit device 60 is in test mode. In addition, system 200 may include different test modes for the operations described above with reference to FIGS. 1, 2, and 3, or these operations may be associated with the same test mode.

When integrated circuit device 60 is in test mode, demultiplexer 208 establishes a communication path between configuration data input pad 202 and configuration registers 204, so that testing module 50 can use configuration data input pad 202 to communicate configuration data to configuration registers 204. When integrated circuit device 60 is not in test mode, demultiplexer 208 establishes a communication path between configuration data input pad 202 and some other portion of the integrated circuit device 60 (represented as internal logic 212 in the illustrated embodiment), so that configuration data input pad 202 may used as an input and/or output even when integrated circuit device 60 is not in test mode. In an alternative embodiment, configuration data input pad 202 may not be used for other purposes when integrated circuit device 60 is not in test mode, and thus, integrated circuit device 60 may not include demultiplexer 208 (coupled to associated internal logic 212).

Configuration registers 204 are organized to operate as a shirt register. In the illustrated embodiment, each configuration registers 204 is a flip-flop which operates according a clock signal 214. When configuration register 204 detects a clocking event, configuration register 204 samples the value at D input 216, stores the value, and communicates the value to Q output 218. In a particular embodiment, the clocking event is the rising edge of clock signal 214 (i.e., when clock signal 214 rises from a low voltage to a high voltage). In an alternative embodiment, the clocking event is the falling edge of clock signal 214 (i.e., when clock signal 214 falls from a high voltage to a low voltage). The first of configuration registers 204 receives the value at D input 216 from configuration data input pad 202. Each of the subsequent configuration registers 204 receives the value at D input 216 from Q output 218 of the preceding configuration register. Once all configuration registers 204 are loaded with configuration data, configuration bits 234 at Q outputs 218, can be used to select the appropriate input paths (as described above in FIG. 1) or output paths (as described above in FIG. 2).

In the particular embodiment illustrated in FIG. 3, the last of configuration registers 204 communicates the value at Q output 218 to inverter 222 and AND gate 224. This layout uses a “lock bit” to stop the shifting of configuration registers 204 when the values are loaded into configuration registers 204. In this particular embodiment, after configuration registers 204 are reset using reset signal 228, the last of configuration registers 204 stores and outputs a “0” (or low voltage) at Q output 218. Inverter 222 receives the “0” and outputs a “1” (or high voltage) to AND gate 224. As a result, AND gate 224 receives CLK pad input 230 and outputs CLK pad input 230 to form clock signal 214. Thus, clock signal 214 is the same as the signal at CLK pad input 230. At each clocking event, configuration registers 204 continue to shift input from configuration data input pad 202. The first value loaded in the first of configuration registers 204 is a “1” or (high voltage). When this initial input value reaches the last of configuration registers 204, that value is communicated to inverter 222. Inverter 222 receives the “1” and outputs a “0” (or low voltage). As a result, AND gate 224 outputs a “0” (or low voltage). This cause configuration registers 204 to stop shifting the configuration data according to CLK pad input 230. In alternative embodiments, integrated circuit device 60 may not use a lock bit to disable CLK pad input 230.

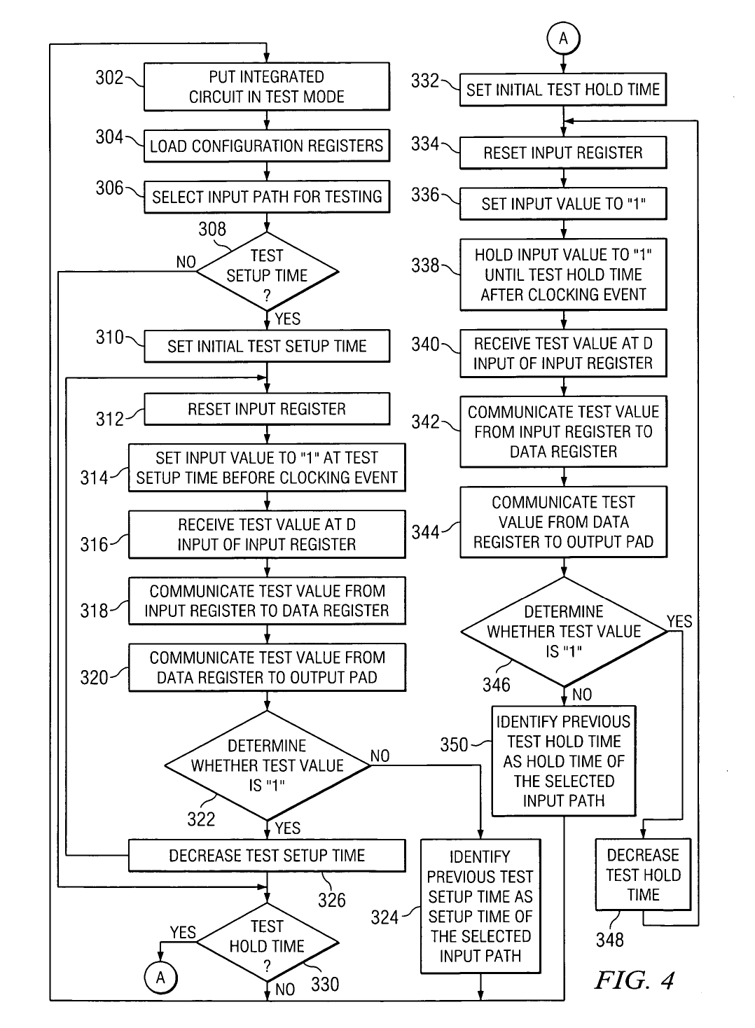

FIG. 4 is a flowchart of a method of testing input characteristics in integrated circuit device 60. The method begins at step 302, where testing module 50 puts integrated circuit device 60 in test mode. In a particular embodiment, testing module 50 communicates a specific value (for example, a “1” or high voltage) to input pad 115 to generate an appropriate test mode signal 116.

At step 304, testing module 50 loads configuration data into configuration registers 28. As explained above with reference to FIG. 3, configuration registers 204 may be arranged to operate as a shift register, and testing module 50 may use one input pad 202 to load configuration data into several configuration registers 204.

At step 306, the configuration data in configuration registers 28 is used to select an input path associated with one of input registers 14 for testing. As explained above with reference to the particular embodiment in FIG. 1, the configuration data in one or more configuration registers 28 may be used to generate control signals to demultiplexer 26, which may select a communication path to one of D inputs 34 associated with one of input registers 14. In an alternative embodiment, input pad 12 may communicate data to only one input register 14, and as a result, steps 304 and 306 may not be necessary.

At step 308, testing module 50 decides whether to test setup time. If testing module 50 decides not to test setups time at step 308, the method continues at step 330, where testing module 50 may test hold time.

If testing module 50 decides to test setup time at step 308, the method continues at step 310 where testing module 50 sets an initial test setup time. In this particular embodiment, testing module 50 sets an initial test setup time that is greater than the expected setup time of the selected input path. As described above with reference to FIG. 1, in an alternative embodiment, the initial test setup time may be less than the expected setup time of the selected input path.

At step 312, input register 14 associated with the selected input path is reset. In a particular embodiment, a reset control signal is used to set input register 14 and data register 16 to “0” (or a low voltage). In an alternative embodiment, a “0” value is loaded into input register 14 and data register 16 using input pad 12.

At step 314, testing module 50 sets the input value at input pad 12 to “1” (or high voltage) at the test setup time before the clocking event. At step 316, input register 14 receives a test value at D input 34 at a clocking event of clock signal 32. At step 318, input register 14 communicates the received test value to associated data register 16. At step 320, data register 16 communicates the test value to output pad 18.

At step 322, testing module 50 determines whether the test value at output pad 18 is a “1” (or high voltage). If the test value is a “1,” input register 14 successfully received the input value at input pad 12 which was set at the test setup time before the clocking event. As a result, testing module 50 decreases the test setup time at step 322, and the method continues at step 312, where testing module 50 evaluates the updated test setup time. If the test value at output pad 18 is not a “1,” then input register 14 did not receive the input value set at the test setup time before the clocking event, and as a result, testing module 50 identifies the previous test setup time as the setup time of the selected input path at step 324 and the method continues at step 302 where testing module 50 may select the same or a different input path for testing.

At step 330, testing module 50 determines whether to test hold time. If testing module 50 decides not to test hold time, the method continues at step 302. If testing module 50 decides to test hold time at step 330, the method continues at step 332.

At step 332, testing module sets an initial test hold time. In this particular embodiment, the test hold time is greater than the expected hold time of the selected input path. As described above with reference to FIG. 1, in alternative embodiments, the initial test hold time may be less than the expected hold time of the selected input path.

At step 334, input registers 14 are reset. In a particular embodiment, a reset control signal is used to set input register 14 and data register 16 to “0” (or a low voltage). In an alternative embodiment, a “0” value is loaded into input register 14 and data register 16 using input pad 12.

At step 336, testing module 50 sets input pad 12 to an input value of “1” (or high voltage). The input value is set at some time before the expected or known setup time of the selected input path. At step 338, testing module 50 holds the input value at input pad 12 to “1” until the test hold time after the next clocking event. At step 340, input register 14 associated with the selected input path receives a test value at D input 34. At step 342, input register 14 communicates the test value to data register 16. At step 344, data register 16 communicates the test value to output pad 18.

At step 346, testing module 50 determines whether the test value at output pad 18 is a “1” (or high voltage). If testing module 50 determines that the test value is a “1,” then input register 14 successfully received the input value from input pad 12 when the input value was held for the test hold time after a clocking event. As a result, testing module 50 decreases the test hold time at step 348, and the method continues at step 334, where testing module 50 can test the operation of the selected input path at the updated test hold time. If testing module 50 determines that the test value at output pad 18 is not a “1” at step 346, input register 14 did not receive the input value held at input pad 12 for the test hold time, and as a result, testing module 50 identifies the previous test hold time as the hold time of the selected input path at step 350. The method returns to step 302, where testing module may continue in the test mode and may select the same or a different input path for testing purposes. Testing module 50 may test the same input path several times to obtain several measurements to ensure that the measurements are precise or statistically significant.

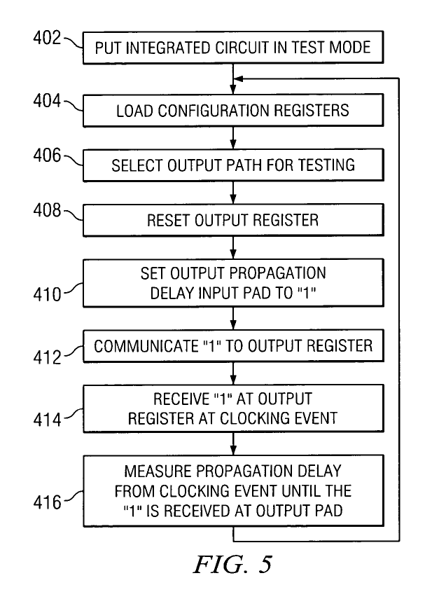

FIG. 5 is a flowchart of a method of testing output characteristics in integrated circuit device 60. The method begins at step 402, where testing module 50 puts integrated circuit device 60 in a test mode. In a particular embodiment, testing module 50 communicates a specific value (for example, a “1” or high voltage) to input pad 115 to generate an appropriate test mode signal 116.

At step 404, testing module 50 loads configuration data into configuration registers 138. As explained above with reference to the particular embodiment of FIG. 3, configuration registers 204 may be arranged to operate as a shift register, and testing module 50 may use one input pad 202 to load configuration data into several configuration registers 204.

At step 406, the configuration data in configuration registers 138 is used to select an output path for testing. As explained above with reference to the particular embodiment of FIG. 2, the configuration data in one or more configuration registers 138 may be used to generate control signals 142 to multiplexer 130, which may select one of the output communication paths from Q outputs 126 of output registers 108 to output pad 110. In an alternative embodiment, output pad 110 may receive data from only one output register 108, and as a result, steps 404 and 406 may not be necessary.

At step 408, output registers 108 are reset. In a particular embodiment, testing module 50 uses a reset control signal to set output registers 108 to “0” (or a low voltage). In an alternative embodiment, testing module 50 uses input pad 102 to communicate a “0” value to D inputs 124 of output registers 108, which receive the “0” at a clocking event of clock signal 122.

At step 410, testing module 50 sets output propagation delay input pad 102 to “1” (or high voltage). At step 412, the input value is communicated to output register 108. At step 414, output register 108 receives the “1” at a clocking event. At step 416, testing module 50 measures the propagation delay or time from the clocking event until the “1” (or high voltage) is received at output pad 110. The method continues at step 404, where testing module 50 may load configuration data to test a different output path. Alternatively, testing module 50 may test the output propagation of the same output path numerous times to obtain several measurements to ensure that the measurements are precise or statistically significant.

Although an embodiment of the invention and its advantages are described in detail, a person skilled in the art could make various alterations, additions, and omissions with departing from the spirit and scope of the present invention as defined by the appended claims.

1. A method of testing input characteristics of an integrated circuit device, comprising:
putting an integrated circuit device into a test mode wherein one or more data registers are operable to receive test values stored at one or more input registers and to communicate the test values to at least one output pad;
receiving an input value at an input pad;
communicating the input value from the input pad to one of the input registers;
receiving a test value at the input register;
communicating the test value from the input register to one of the data registers; and
communicating the test value from the data register to the output pad.

2. The method of claim 1, further comprising:
comparing the test value with the input value; and
determining that the input register received the input value from the input pad if the test value matches the input value.

3. The method of claim 1, further comprising:
selecting the input register from a plurality of input registers that may receive the input value from the input pad; and
communicating the input value from the input pad to the selected input register.

4. The method of claim 1, further comprising:
selecting a test setup time;
communicating the input value to the input pad at the test setup time before a next clocking event; and
receiving the test value at the input register at the next clocking event.

5. The method of claim 1, further comprising:
selecting a test hold time;
maintaining the input value at the input pad for the test hold time after a clocking event; and
receiving the test value at the input register at the next clocking event.

6. The method of claim 1, wherein communicating the test value from the data register to the output pad comprises shifting the test value through a serial chain of data registers to the output pad.

7. A system for testing input characteristics of an integrated circuit device, comprising an integrated circuit device comprising:
an input pad;
an output pad;
an input register operable to receive an input value from the input pad and to communicate the input value to a portion of the integrated circuit for processing when the integrated circuit is not in test mode; and
a data register operable to receive a test value from the input register and to communicate the test value to the output pad when the integrated circuit is in test mode.

8. The system of claim 7, wherein the integrated circuit further comprises one or more configuration registers operable to select the input register from a plurality of input registers that may receive the input value from the input pad.

9. The system of claim 7, further comprising a testing module operable to communicate the input value to the input pad, to receive the test value from the output pad, to compare the test value with the input value, and to determine that the input register received the input value from the input pad if the test value matches the input value.

10. The system of claim 7, further comprising a testing module operable to select a test setup time, to communicate the input value to the input pad at the test setup time before a next clocking event, to receive the test value from the output pad, to compare the test value with the input value, and to determine that the input register received the input value from the input pad if the test value matches the input value.

11. The system of claim 7, further comprising a testing module operable to selecting a test hold time, to communicate the input value to the input pad, to maintain the input value at the input pad for the test hold time after a clocking event, to receive the test value from the output pad, to compare the test value with the input value, and to determine that the input register received the input value from the input pad if the test value matches the input value.

12. The system of claim 7, wherein the data register communicates the test value from to the output pad by shifting the test value through a serial chain of data registers.

13. A method of testing output characteristics of an integrated circuit device comprising:
putting an integrated circuit device into a test mode wherein at least one input pad is operable to receive an input value and to communicate the input value to one or more output registers;
receiving an input value at the input pad;
communicating the input value from the input pad to an output register; and
communicating the input value from the output register to an output pad.

14. The method of claim 13, further comprising measuring a propagation delay from a clocking event until the input value is received at the output pad.

15. The method of claim 13, further comprising:
selecting the output register from a plurality of output registers that can communicate the input value to the output pad; and
communicating the input value from the selected output register to the output pad.

16. A system for testing input characteristics of an integrated circuit device, comprising:
an integrated circuit device comprising:
an input pad operable to receive an input value for use in testing propagation delay;
an output pad;
a output register operable to receive the input value from the input pad when the integrated circuit device is in test mode and to communicate the input value to the output pad in response to a clock event.

17. The system of claim 16, wherein the integrated circuit further comprises a multiplexer operable to communicate the input value to the output register when the integrated circuit is in test mode.

18. The system of claim 16, further comprising a testing module operable to communicate the input value to the input pad of the integrated circuit device, to receive the input value from the output pad of the integrated circuit device, and to measure a propagation delay from a clocking event until the input value is received at the output pad.

19. The integrated circuit of claim 6, further comprising configuration registers operable to select the output register from a plurality of output registers that can communicate the input value to the output pad.
